(19) United States
(12) Patent Application Publication
(10) Pub. No.: US 2008/0014678 A1
(43) Pub. Date: Jan. 17, 2008

(54) System and method of attenuating electromagnetic interference with a grounded top film

(75) Inventors: Gregory Eric Howard, Dallas, TX (US); Vikas Gupta, Dallas, TX (US); Wilmar Sibido, Garland, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/486,711

(22) Filed: Jul. 14, 2006

(51) Int. Cl. H01L 21/00

(52) U.S. Cl. 438/106

(57) ABSTRACT

A plastic integrated circuit package often includes one or more integrated circuit elements that are sensitive to outside electromagnetic fields and also may generate electromagnetic fields that may interfere with other circuits outside of the package. The package herein has a top metal film to attenuate such electromagnetic fields, using a wire loop extending through the encapsulating compound to the metal film on top of encapsulating compound to provide electrical connection between top EMI film and end-and-ground junctions at grounds on die or on end-and-ground junctions at grounds on substrate.

### FIELD OF THE INVENTION

The present invention relates generally to the field of electronic circuits and, more particularly, to shielding plastic encapsulated circuits from electromagnetic interference.

### BACKGROUND OF THE INVENTION

Electrical devices generally emit electrical fields, magnetic fields, or a combination of both (electromagnetic fields). For example, an integrated circuit structure (e.g., an integrated circuit chip) within an electrical device may emit one or more electrical fields, magnetic fields, or electromagnetic fields, which may result in the electrical device emitting such one or more fields. An electromagnetic field emitted from one electrical device may interfere with another electrical device. This interference may be referred to as electromagnetic interference (EMI). As an example, electrical devices may emit radio frequency (RF) signals, microwave signals, or other electromagnetic signals, which may interfere with other electrical devices.

Additionally, the electronics industry has seen an increase in clock speeds of electrical devices, use of RF signals in electrical devices, and integration of functions in integrated circuit chips. These factors have resulted in increased EMI. The United States Federal Communications Commission (FCC) has set limits on the acceptable levels of EMI signals an electrical device may emit. Current solutions for limiting EMI include encasing electrical devices in special metallic shielding (e.g., a metal casing or a plastic casing sprayed with metallic paint), often referred to as a Faraday shield. At the integrated circuit structure level, solutions include enclosing entire integrated circuit chips in metal. However, using the metal casing is generally an expensive solution, which may also present certain limitations in the design and manufacture of electrical devices. Additionally, spraying a plastic casing with a metallic paint may be costly and often adds a burdensome step to the manufacture of electrical devices.

### SUMMARY OF THE INVENTION

Many electronic integrated circuits are encapsulated in plastic. A standard overmolded process uses a single molded cavity with a number of integrated circuits being encapsulated in the same cavity, and then uses a sawing process (package singulation) for dividing the single molded unit into multiple packages. However it is not possible as part of this regular package processing to use a thin metal layer to protect the package from EMI due to the fact that the metal layer needs to be connected to ground to be effective. The present invention provides an easy and cost effective method for forming that connection, thus making EMI/ESD protection of these devices possible at a low cost.

In a standard single overmold cavity process, the spacing between the packages is minimized to minimize the substrate costs, and this minimization led to the use of a saw singulation process for the packages. In the past processes, thin layers of metallization were plated to the surface of the mold cap for each individual package cavity with connection achieved by plating to specific ground connections on the substrate which were exposed for this very purpose. The saw singulation process does not leave any surface of the substrate exposed for this purpose, thus this past process is unavailable.

In one embodiment, the present invention solves the problem of creating a connection to the metal layer over the mold material by using a grounded wirebond (with a package-high loop) from the die/substrate to the top of the mold cap (and, e.g. back to the die/substrate connected to the ground bus on the die/substrate). After the molding is completed, the wire loops that have been added are exposed at the surface of the mold cap for all the packages prior to saw singulation. This exposure can be further enhanced by a dry etch process to guarantee a good electrical connection to these gold wires. A thin 100 to 1000 Angstrom metal layer (e.g., Al, copper, gold or other metal that does not corrode easily) can be sputtered to the surface of the package to act as an EMI/ESD protective layer. The metallization can act to attenuate electromagnetic waves incident upon this layer and contain them within or outside the package.

The present invention can also be a method of providing electrical connections between top EMI films and ground for molded packages having a package height and containing an integrated circuit (e.g., single chip configuration, stacked chip configuration, flip chip configuration, multi-chip configuration, etc.). The method may include the steps of providing a first integrated circuit die on a first substrate area, and an at least package-height wirebond with at least one end connected to a ground either on the first substrate area or on the first integrated circuit, providing a second integrated circuit die on a second substrate area and an at least package-height wirebond with at least one end connected to a ground either on the second substrate area or on the second integrated circuit, encapsulating the first and second integrated circuits and first and second areas of the substrate with insulating mold-material, and depositing a metal film in electrical connection with the wirebonds. The wirebonds provide electrical connections between the metal film and grounds of the substrate areas, or on the first or second integrated circuit. Cutting can provide separate packages, wherein each package has a substrate, an integrated circuit, encapsulating mold-material, a portion of the metal film, and a wirebond electrical connection, whereby the portion of the metal film serves as an EMI film, and a wirebond electrical connection grounds the EMI film.

Preferably, the integrated circuit dies and areas of substrate are placed in a mold cavity that is then filled with insulating mold-material that substantially covers the package height wirebonds, and the insulating mold-material is then etched to expose a portion of the package height wirebonds. A top EMI film can be sputtered over the insulating mold-material, and over and in electrical connection with exposed portions of the package height wirebonds. Wirebonds of more than package height will generally be bent down to about package height when inserted in an injection molding cavity.

The EMI film can be of aluminum, copper, or gold and the EMI film can be between 100 and 1,000 Angstroms thick. Preferably wirebonds used for EMI-film grounding are grounded on both ends (e.g. die to die, die to substrate, or substrate to substrate). More than one EMI-film grounding wirebonds can be used in a package (e.g. near opposites corners of the package. Two package height wires (or even more) can be used together in a crossing configuration provide a reinforced EMI-film grounding connection, and both ends of both wires are preferably grounded.

The present invention also provides a molded integrated circuit package having an electrical connection between a top EMI film and ground inside the molded package. More specifically, the present invention may include an integrated circuit (e.g., single chip configuration, stacked chip configuration, flip chip configuration, multi-chip configuration, etc.) with at least two less-than-package-height bondwires to a substrate and a package-height wirebond, with the package-height wirebond having at least one end connected to a ground either on the substrate or on the integrated circuit, an insulating mold-material covering the integrated circuit and substrate with to a height greater than the less-than-package-height bondwires, but not greater than the package-height loop wirebond, and a top EMI film over the insulating mold-material and in electrical connection with a portion of the package-height wirebond. Thus the package-height wirebond provides an electrical connection between a top EMI film and a ground on the substrate or the integrated circuit, providing a package with a EMI film grounded by a wire inside the molded package.

In addition, the present invention a method for providing an electrical connection between a top EMI film and ground for a molded package containing at least a first semiconductor die that includes the steps of providing wirebonds between the die and a first substrate area using first and second loop wirebonds having first and second heights, and providing a third wirebond having a wirebond end connected either to a ground on the first substrate area or to a ground on the die, with the third wirebond having a height greater than the heights of the first and second wirebonds, covering the die with insulating mold-material to a height greater than the heights of the first and second wirebonds, and depositing a top EMI film in electrical connection with an exposed portion of the third wirebond, wherein the third wirebond provides an electrical connection between a top EMI film and either a ground of the substrate, or a ground on the die.

As a plastic integrated circuit package often includes one or more integrated circuit elements (e.g., single chip configuration, stacked chip configuration, flip chip configuration, multi-chip configuration, etc.) that are sensitive to outside electromagnetic fields and also may generate electromagnetic fields that may interfere with other circuits outside of the package, the structure and method herein uses a top metal film to attenuate such electromagnetic fields, using a wire loop extending through the encapsulating compound to the top of the encapsulating compound provide electrical connection between top EMI film and package ground.

The present invention is described in detail below with reference to the accompanying drawings.

### BRIEF DESCRIPTION OF THE DRAWINGS

The above and further advantages of the invention may be better understood by referring to the following description in conjunction with the accompanying drawings, in which:

FIGS. 1A and 1B illustrate a cross-sectional view and top view of an example of an array integrated circuits prior to being separated into packages;

FIG. 2 illustrates an array section prior to deposition of an EMI-film, with wirebonds to be used as EMI-film grounding wirebonds with both ends bonded to a die;

FIG. 3 illustrates an array section prior to deposition of an EMI-film, with wirebonds to be used as EMI-film grounding wirebonds with both ends bonded to a is substrate;

FIG. 4 illustrates an array section prior to deposition of an EMI-film, with wires to be used as EMI-film grounding wirebonds with the wires in crossing configurations to provide reinforced EMI-film grounding connections and with all ends bonded to a substrate; and

FIG. 5 illustrates a separated package with EMI-film grounding wirebonds with one end bonded to a die and the other end bonded to a substrate.

### DETAILED DESCRIPTION OF THE INVENTION

While the making and using of various embodiments of the present invention are discussed in detail below, it should be appreciated that the present invention provides many applicable inventive concepts that can be embodied in a wide variety of specific contexts. The specific embodiments discussed herein are merely illustrative of specific ways to make and use the invention and do not delimit the scope of the invention.

In one embodiment, the present invention solves the problem of creating a connection to the metal layer over the mold material by using a grounded wirebond (with a package-high loop) from the die/substrate to the top of the mold cap (and, e.g. back to the die/substrate connected to the ground bus on the die/substrate). After the molding is completed, the wire loops that have been added are exposed at the surface of the mold cap for all the packages prior to saw singulation. This exposure can be further enhanced by a dry etch process to guarantee a good electrical connection to these gold wires. A thin 100 to 1000 Angstrom metal layer (e.g., Al, copper, gold or other metal that does not corrode easily) can be sputtered to the surface of the package to act as an EMI/ESD protective layer. The metallization can act to attenuate electromagnetic waves incident upon this layer and contain them within or outside the package.

The integrated circuit structure may include one or more integrated circuit elements operable to generate an electromagnetic field when an electric current is applied to the integrated circuit. The structure also includes an encapsulating compound (mold material) substantially surrounding the one or more integrated circuits on a substrate. A wire loop extending through the encapsulating compound to the top of the encapsulating compound provides electrical connection between top EMI film and package ground.

The present invention can also be a method of providing electrical connections between top EMI films and ground for molded packages having a package height and containing an integrated circuit (e.g., single chip configuration, stacked chip configuration, flip chip configuration, multi-chip configuration, etc.). The method may include the steps of providing a first integrated circuit die on a first substrate area, and an at least package-height wirebond with at least one end connected to a ground either on the first area or on the first integrated circuit, providing a second integrated circuit die on a second substrate area and an at least package-height wirebond with at least one end connected to a ground either on the second substrate area or on the second integrated circuit, encapsulating the first and second integrated circuits and first and second areas of the substrate with insulating mold-material, and depositing a metal film in electrical connection with the wirebonds. The wirebonds provide electrical connections between the metal film and grounds of the substrate areas, or on the first or second integrated circuit. Cutting can provide separate packages, wherein each package has a substrate, an integrated circuit, encapsulating mold-material, a portion of the metal film, and a wirebond electrical connection, whereby the portion of the metal film serves as an EMI film, and a wirebond electrical connection grounds the EMI film.

Note the initial filling of mold material may be later reduced by etching (or polishing) down to a final package height and thus that the package-height wirebonds may be initially either shorter than the package height and then exposed during etching of the mold material down to the final package height, or greater than package height and pushed down to the final package height during the injection molding process (or pushed down to below the final package height during the injection molding process and then exposed during etching of the mold material down to the final package height). In the final package the top of the package-height wirebonds is to be at the level of and making electrical contact to the EMI film.

In a single overmold cavity process, the spacing between the packages is minimized to minimize the substrate costs, and this minimization led to the use of a saw singulation process for the packages. In the past processes, thin layers of metallization were plated to the surface of the mold cap for each individual package cavity with connection achieved by plating to specific ground connections on the substrate which were exposed for this very purpose. The saw singulation process does not leave any surface of the substrate exposed for this purpose, thus this past process is unavailable.

The present invention also provides a method of providing an electrical connection between a top EMI film and ground for a molded package containing at least a first semiconductor die (e.g., single chip configuration, stacked chip configuration, flip chip configuration, multi-chip configuration, etc.). The method may include the steps of providing wires between the die and a first substrate area using first and second loop bondwires having first and second heights, and providing a third wirebond having a wirebond end connected either to a ground on the first substrate area or to a ground on the die, with the third wirebond having a height greater than the heights of the first and second bondwires, covering the die with insulating mold-material to a height greater than the heights of the first and second bondwires, and depositing a top EMI film in electrical connection with an exposed portion of the third wirebond, wherein the third wirebond provides an electrical connection between a top EMI film and either a ground of the substrate, or a ground on the die. The covering the die with deposited insulating mold-material can also be with at least substantially covering of the third wirebond, and the insulating mold-material is then being etched to expose a portion of the third wirebond, but not expose either of the first or second bondwires. In some of these embodiments, a second semiconductor dies is wired to second area of the substrate with the second die having fourth and fifth bondwires with fourth and fifth heights, and providing a sixth wirebond having a wirebond end connected either to a ground on the second substrate area or to a ground on the second die, with the sixth loop wirebond having a height greater than the heights of the fourth and fifth loop wirebonds, and wherein the first and second dies and the first and second substrate areas are covered with insulating mold-material to a height greater than the heights of the first, second, fourth, and fifth bondwires, and a top EMI film in electrical connection with the third and sixth wirebonds is deposited over the dies and the substrate areas, and wherein sawing then provides separate packages, with each package having a substrate, integrated circuit mold-material, a top EMI film, and electrical connections between a top EMI films and ground, with a first package containing the first die and a second package containing the second die. Preferably, a saw singulation process is used in separating the packages. The EMI film is preferably sputtered onto the exposed portion of the third (top-film-grounding) loop wirebond and onto a top surface of the insulating mold-material and the EMI film is preferably of aluminum, copper, or gold and between 100 and 1,000 Angstroms thick and the die is preferably an integrated circuit.

In some embodiments of these embodiments, at least two wirebonds are used in a contacting crossing configuration provide a reinforced EMI-film grounding connection. Thus wires may be supported by a crossing two wire loops with the wires preferably touching at the apex such that a top view, not shown, would show the two crossing wire loops making an “X” (not necessarily at right angles). Crossing wire loops preferably have wire ends bonded to the substrate, but wire ends bonded to the die could be used.

The insulating mold-material can be injected with a mold-sweep profile that avoids excess lowering of the height of the top-film-grounding wirebond, thus generally avoiding a wirebond height in which the EMI film does not make electrical contact with the wirebond.

The insulating mold-material may be injected with a mold-sweep profile that lowers heights of the top-film-grounding loop wirebond to a lower height, as long as the etch still exposes a portion of the top-film-grounding loop wirebond.

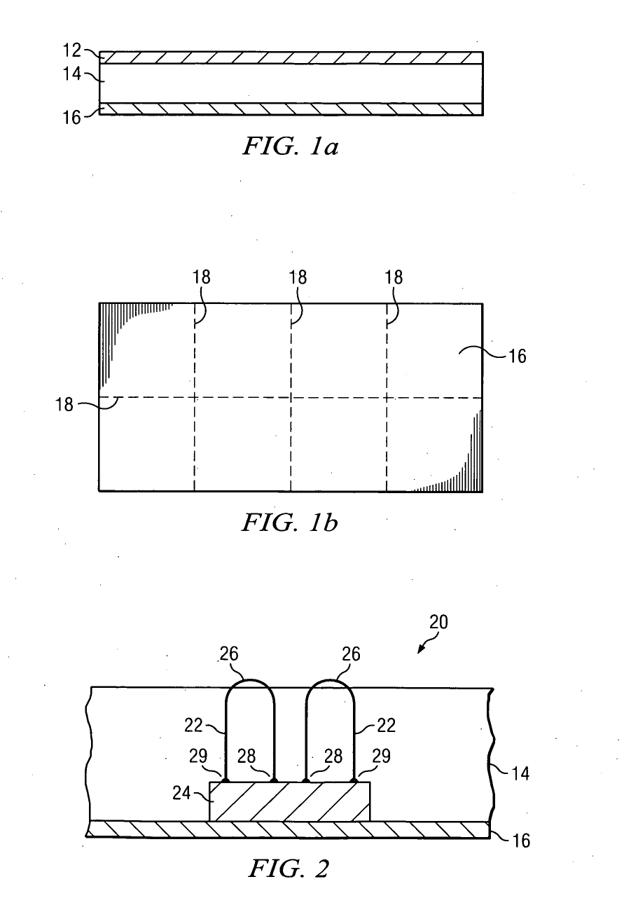

FIGS. 1A and 1B illustrate a cross-sectional view and a bottom view, respectively, of an array of integrated circuits (e.g., single chip configuration, stacked chip configuration, flip chip configuration, multi-chip configuration, etc.) prior to being separated into packages. The array 10 has a metal film 12 to provide EMI shielding, mold material 14, and a ground-containing substrate 16. Cutting lines 18 in FIG. 1B show where the array can be cut to provide individual packages (here, 8 packages). While such an array is relatively inexpensive to fabricate, it would be expensive to externally ground the EMI shielding, and herein an inexpensive wire loop extending internally through the encapsulating compound to the top of the encapsulating compound provides electrical connection between top EMI film and package ground, as described below.

FIG. 2 illustrates an array section 20 prior to deposition of an EMI-film, with wirebonds 22 to be used as EMI-film grounding wirebonds with bonds to an integrated circuit die 24 on substrate 16. Mold material 14 covers die 24 on substrate 16 and largely surrounds wirebonds 22 except for exposed portions 26. Wirebonds 32 have both end-and-ground junctions 28, 29 at grounds on integrated circuit die 24.

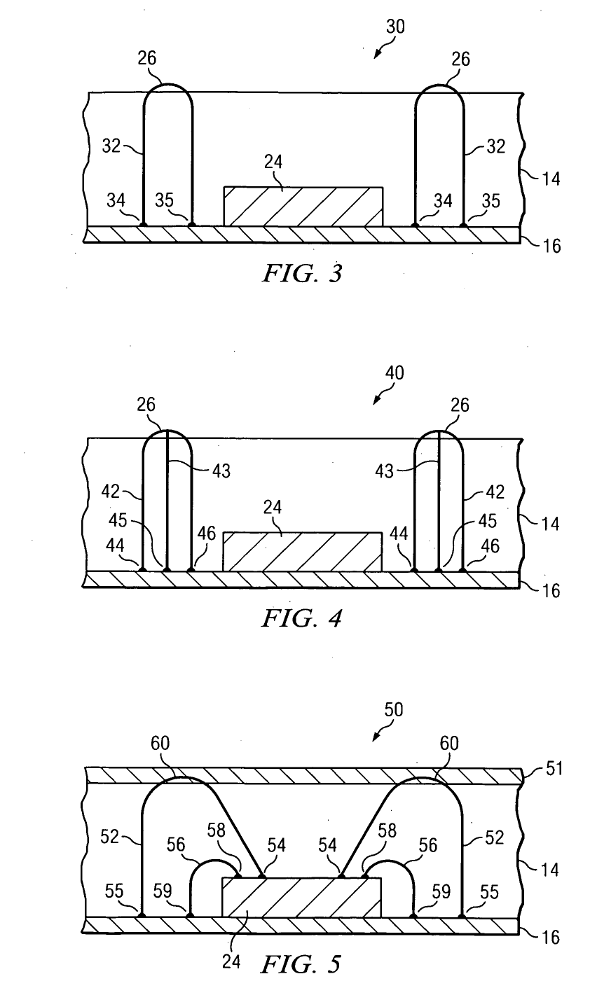

FIG. 3 illustrates an alternate array section 30 prior to deposition of an EMI-film, with wirebonds 32 to be used as EMI-film grounding wirebonds. Wirebonds 32 have both end-and-ground junctions 34, 35 at grounds on substrate 16.

FIG. 4 illustrates a further alternate array section 40 prior to deposition of an EMI-film, with wires 42 to be used as EMI-film grounding wirebonds with the wires in crossing configurations to provide reinforced EMI-film grounding connections. Thus wires 42 are supported by a crossing wire loops 43 (such that a top view, not shown, would show wires 42 and crossing wire loops 43 as making an “X”. Crossing wire loops 43 have wire ends 45 bonded to substrate 16, and wires 42 have wire end-and-ground junctions 44, 46 at grounds on substrate 16.

FIG. 5 illustrates a separated package 50 with EMI-film 51 grounded by wirebonds 52 with one end 54 bonded to die 24 and the other end 55 bonded to substrate 16. Also shown are regular bondwires 56 with one end-and-ground junctions 58 at grounds on die 24 and the other end 59 at grounds on substrate 16. While one end of a grounding wirebond could be either unbonded or bonded to an electrically isolated metal pad, it is preferred that both ends of grounding wirebonds be grounded.

Thus the present invention can also be a molded integrated circuit package 50 having an electrical connection between a top EMI film 51 and ground inside the molded package 50, that includes an integrated circuit 24 with at least two less-than-package-height bondwires 56 to a substrate 16 and an at least one package-height wirebond 52, with the package-height wirebond 52 having at least one end connected to a ground either on the substrate 16 or on the integrated circuit 24, an insulating mold-material 14 covering the integrated circuit 24 and substrate 16 with to a height greater than the less-than-package-height bondwires 56, but not greater than the package-height loop wirebond 52, and a top EMI film 51 over the insulating mold-material 14 and in electrical connection with a portion of the package-height wirebond 52, whereby the package-height wirebond 52 provides an electrical connection between a top EMI film 51 and is grounded on the substrate 16 or the integrated circuit 24, providing a package with an EMI film 51 grounded by a wire 52 inside the molded package 50. Again note that the package-height wirebonds 52 may be initially either shorter than the package height and then exposed during etching of the mold material down to the final package height; or greater than package height and pushed down to the final package height during the injection molding process (or pushed down to above the final package height during the injection molding process and then exposed during etching of the mold material down to the final package height).

It may be noted that an alternate approach to attenuating EMI is described in published patent application 20050206015 “System and method for attenuating electromagnetic interference” to Salzman, et al, which describes use of an encapsulating compound includes an electromagnetic field-attenuating material for attenuating electromagnetic interference.

Although the present invention has been described with several embodiments, diverse changes, substitutions, variations, alterations, and modifications may be suggested to one skilled in the art, and it is intended that the invention encompass all such changes, substitutions, variations, alterations, and modifications as fall within the spirit and scope of the appended claims.

What is claimed is:

1. A method of providing electrical connections between top EMI films and ground for molded packages having a package height and containing an integrated circuit, comprising the steps of:
providing a first integrated circuit die on a first substrate area, and an at least package-height wirebond with at least one end connected to a ground either on said first substrate area or on said first integrated circuit;
providing a second integrated circuit die on a second substrate area and an at least package-height wirebond with at least one end connected to a ground either on said second substrate area or on said second integrated circuit;
encapsulating said first and second integrated circuits and first and second areas of said substrate with insulating mold-material;
depositing a metal film in electrical connection with said package-height wirebonds, wherein said package-height wirebonds provide electrical connections between said metal film and grounds of said substrate, or of said first integrated circuit, or of said second integrated circuit; and
cutting to provide separate packages, wherein each package has a substrate, an integrated circuit, encapsulating mold-material, a portion of the metal film, and a wirebond electrical connection, whereby the portion of said metal film serves as an EMI film, and a wirebond electrical connection grounds the EMI film.

2. The method of claim 1, wherein said integrated circuits and said areas of substrate are placed in a mold cavity, and the cavity is then filled with insulating mold-material that substantially covers said wirebonds, and said insulating mold-material is then etched to expose a portion of said package height wirebonds.

3. The method of claim 1, wherein said top EMI film is sputtered over said insulating mold-material, and over and in electrical connection with exposed portions of said package height wirebonds.

4. The method of claim 1, wherein said EMI film is between 100 and 1,000 Angstroms thick and is EMI film is of aluminum, copper, or gold.

5. The method of claim 1, wherein two package height wires are used together in a crossing configuration provide one reinforced EMI-film grounding connection.

6. The method of claim 1, wherein each integrated circuit die comprises a single chip configuration, a stacked chip configuration, a flip chip configuration or a multi-chip configuration.

7. A molded integrated circuit package having a package height, and having an electrical connection between a top EMI film and a ground inside the molded package, comprising:
an integrated circuit with at least two less-than-package-height bondwires to a substrate and a package-height wirebond, with said package-height wirebond having at least one end connected to a ground either on said substrate or on said first integrated circuit;
an insulating mold-material covering said integrated circuit and substrate with to a height greater than said less-than-package-height bondwires, but not greater than said package-height loop wirebond; and
a top EMI film over said insulating mold-material and in electrical connection with a portion of said package-height wirebond, whereby said package-height wirebond provides an electrical connection between a top EMI film and a ground on said substrate or said integrated circuit, providing a package with a EMI film grounded by a wire inside the molded package.

8. The package of claim 7, wherein said integrated circuit package having an electrical connection between top EMI film and ground has been separated from substantially similar packages by cutting between said packages.

9. The package of claim 7, wherein said top EMI film is 100 to 1,000 Angstrom thick and is of aluminum, copper or gold.

10. The package of claim 7, wherein said package-height wirebond is made with two wires in a crossing configuration.

11. The package of claim 7, wherein said integrated circuit die comprises a single chip configuration, a stacked chip configuration, a flip chip configuration or a multi-chip configuration.

12. A method of providing an electrical connection between a top EMI film and ground for a molded package containing at least a first semiconductor die, comprising the steps of:
providing wires between said die and a first substrate area using first and second loop bondwires having first and second heights, and providing a third wirebond having a wirebond end connected either to a ground on said first substrate area or to a ground on said die, with said third wirebond having a height greater than said heights of said first and second bondwires;
covering said die with insulating mold-material to a height greater than said heights of said first and second bondwires; and
depositing a top EMI film in electrical connection with an exposed portion of said third wirebond, wherein said third wirebond provides an electrical connection between a top EMI film and either a ground of said substrate, or a ground on said die.

13. The method of claim 12, wherein said covering said die with deposited insulating mold-material also at least substantially covers said third wirebond, and said insulating mold-material is then etched to expose a portion of said third wirebond, but not expose either of said first or second bondwires.

14. The method of claim 12, wherein a second semiconductor die is wired to second area of said substrate with said second die having fourth and fifth bondwires with fourth and fifth heights, and providing a sixth wirebond having a wirebond end connected either to a ground on said second substrate area or to a ground on said second die, with said sixth loop wirebond having a height greater than said heights of said fourth and fifth loop bondwires, and wherein said first and second dies and said first and second substrate areas are covered with insulating mold-material to a height greater than said heights of said first, second, fourth, and fifth bondwires, and a top EMI film in electrical connection with said third and sixth wirebonds is deposited over said dies and said substrate areas, and wherein sawing then provides separate packages, with each package having a substrate, integrated circuit mold-material, a top EMI film, and electrical connections between a top EMI films and ground, with a first package containing said first die and a second package containing said second die.

15. The method of claim 14, wherein a saw singulation process is used in separating said packages.

16. The method of claim 12, wherein said EMI film is sputtered onto said exposed portion of said third loop wirebond and onto a top surface of said insulating mold-material.

17. The method of claim 12, wherein:
said EMI film is between 100 and 1,000 Angstroms thick and is of aluminum, copper, or gold; and
said die comprises an integrated circuit in a single chip configuration, a stacked chip configuration, a flip chip configuration or a multi-chip configuration.

18. The method of claim 12, wherein at least two third wirebonds are used in a contacting crossing configuration provide a reinforced EMI-film grounding connection.

19. The method of claim 12, wherein said insulating mold-material is injected with a mold-sweep profile that avoids excess lowering of the height of said third wirebond, thus avoiding a wirebond height in which the EMI film does not make electrical contact with said third wirebond.

20. The method of claim 13, wherein said insulating mold-material is injected with a mold-sweep profile that avoids lowering heights of said third loop wirebond to a height such that said etch does not expose said third loop wirebond.
